(19) United States
(12) Patent Application Publication
(10) Pub. No.: US 2022/0026481 A1
(43) Pub. Date: Jan. 27, 2022

(54) CONTACT TERMINAL, INSPECTION JIG, AND INSPECTION APPARATUS

(71) Applicant: NIDEC READ CORPORATION, Kyoto (JP)

(72) Inventors: Norihiro OTA, Kyoto (JP); Michio KAIDA, Kyoto (JP)

(21) Appl. No.: 17/421,739

(22) PCT Filed: Dec. 19, 2019
(86) PCT No.: PCT/JP2019/049797

§ 371 Date: Jul. 9, 2021

(30) Foreign Application Priority Data
Jan. 10, 2019 (JP) 2019-002395

(51) Int. Cl. G01R 31/26; G01R 1/073; G01R 31/68

(52) U.S. Cl. CPC G01R 31/2607; G01R 31/68; G01R 1/073

(57) ABSTRACT

A probe includes a tubular body having conductivity and a tubular shape, and a first central conductor having conductivity and a stick shape. The tubular body has a cross section perpendicular to an axial direction, the cross section having a shape that is rectangular or hexagonal, and the first central conductor includes a first insertion portion having a cross section perpendicular to an axial direction of the first central conductor, the cross section having a shape that is same as the shape of the cross section of the tubular body, the first insertion portion being inserted into one end portion side of the tubular body, and a first projecting portion projecting from one end portion of the tubular body.

### CROSS-REFERENCE TO RELATED APPLICATIONS

This is a U.S. national stage of application, filed under 35 U.S.C. § 371 of International Patent Application No. PCT/JP2019/049797, filed on Dec. 19, 2019, which claims priority under 35 U.S.C. § 119(a) and 35 U.S.C. § 365(b) from Japanese Patent Application No. 2019-002395, filed on Jan. 10, 2019; the disclosures of which are incorporated herein by reference.

### FIELD

The present invention relates to a contact terminal used to inspect an inspection target, an inspection jig to bring the contact terminal into contact with the inspection target, and an inspection apparatus including the inspection jig.

### BACKGROUND

Conventionally, there has been known a coil spring probe that includes a contact pin having a contact that comes into contact with a conductive pad of a measurement object and a cylindrical tubular body into which a columnar guide extending on a straight line of the contact of the contact pin is inserted, and a part of a peripheral wall of the tubular body is a spring. A plurality of the coil spring probes are arranged side by side, and are brought into contact with a plurality of conductive pads of a measurement object.

In recent years, miniaturization of a semiconductor substrate and a circuit substrate as a measurement object has been progressing. For this reason, an adjacent pitch of the measurement object becomes small. When the adjacent pitch of the measurement object becomes small, an adjacent pitch of the coil spring probe also needs to be small. In order to reduce the adjacent pitch of the coil spring probe to a certain extent or more, it is necessary to thin the tubular body and the guide.

However, there has been a problem that, when the tubular body and the guide element through which current for measurement flows are thinned, a cross-sectional area of a conductor is reduced, which increases a resistance value of the probe.

### SUMMARY

An exemplary contact terminal according to the present disclosure includes a tubular body having conductivity and a tubular shape, and a first central conductor having conductivity and a stick shape. The tubular body has a cross section perpendicular to an axial direction, the cross section having a shape that is rectangular. The first central conductor includes a first insertion portion having a cross section perpendicular to the axial direction, the cross section having a shape that is rectangular, the first insertion portion being inserted into one end portion side of the tubular body, and a first projecting portion projecting from one end portion of the tubular body.

Further, an exemplary inspection jig according to the present disclosure includes a plurality of the contact terminals described above and a support member that supports a plurality of the contact terminals.

Further, an exemplary inspection apparatus according to the present disclosure includes the inspection jig described above and an inspection processing unit that performs an inspection of an inspection target on the basis of an electrical signal obtained by bringing the contact terminal into contact with an inspection point provided on the inspection target.

The above and other elements, features, steps, characteristics and advantages of the present disclosure will become more apparent from the following detailed description of the preferred embodiments with reference to the attached drawings.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments are described with reference to the following drawings, in which:

FIG. 1 is a conceptual diagram schematically illustrating a configuration of a semiconductor inspection apparatus provided with a probe according to an embodiment of the present disclosure;

FIG. 2 is a schematic cross-sectional view illustrating an example of a configuration of an inspection jig illustrated in FIG. 1;

FIG. 3 is a front view illustrating a specific configuration of the probe illustrated in FIG. 2;

FIG. 4 is an explanatory view illustrating the probe illustrated in FIG. 3 exploded into a tubular body, a first central conductor, and a second central conductor;

FIG. 5 is a cross-sectional view taken along line V-V in FIG. 3;

FIG. 6 is a plan view of the inspection jig illustrated in FIG. 2 as viewed from below;

FIG. 7 is an explanatory view for describing an effect of the probe and the inspection jig illustrated in FIG. 2;

FIG. 8 is a schematic cross-sectional view illustrating an inspection state in which the inspection jig illustrated in FIG. 2 is attached to a first pitch conversion block and a tip portion of the probe is pressed against a bump;

FIG. 9 is a front view illustrating the probe when a first spring portion and a second spring portion illustrated in FIG. 3 are compressed;

FIG. 10 is a cross-sectional view of the probe in a compressed state illustrated in FIG. 9 taken along a cutting line X;

FIG. 11 is a front view illustrating a variation of the probe illustrated in FIG. 3;

FIG. 12 is a front view illustrating the probe when the first spring portion and the second spring portion illustrated in FIG. 11 are compressed;

FIG. 13 is a perspective view illustrating a pogo pin which is another variation of the probe illustrated in FIG. 3;

FIG. 14 is a cross-sectional view taken along line XIV-XIV illustrated in FIG. 13;

FIG. 15 is a front view illustrating a variation of the probe illustrated in FIG. 3;

FIG. 16 is a cross-sectional view illustrating a variation of a cross-sectional shape illustrated in FIG. 5; and

FIG. 17 is a perspective view illustrating a variation of the first central conductor.

### DETAILED DESCRIPTION

Hereinafter, embodiments of the present disclosure will be described with reference to drawings. Note that configurations with the same reference numerals in the drawings indicate the same configurations and are omitted from description.

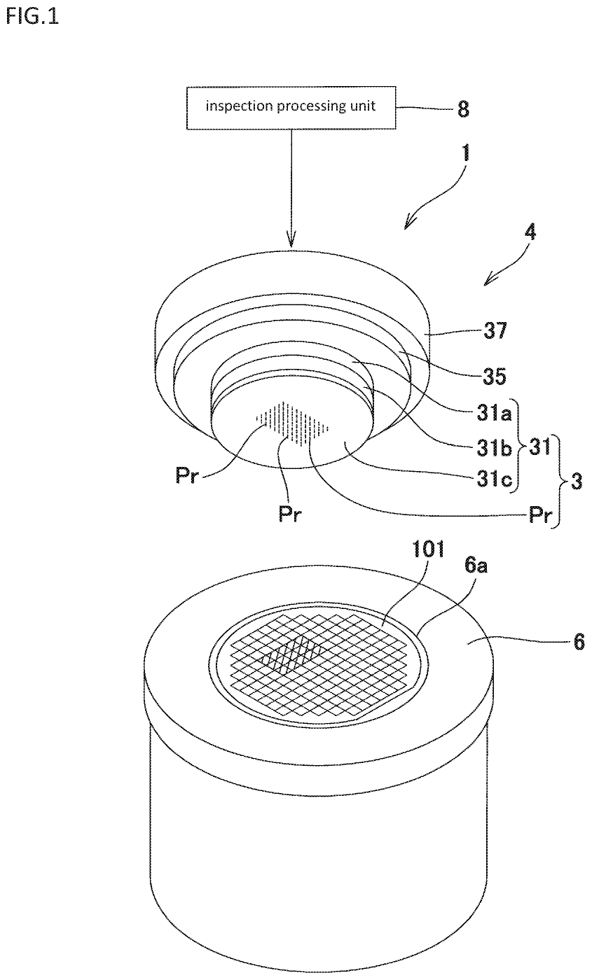

A semiconductor inspection apparatus 1 illustrated in FIG. 1 corresponds to an example of an inspection apparatus. The semiconductor inspection apparatus 1 illustrated in FIG. 1 is an inspection apparatus for inspecting a circuit that is formed on a semiconductor wafer 101 that is an example of an inspection target.

In the semiconductor wafer 101, circuits corresponding to a plurality of semiconductor chips are formed, for example, on a semiconductor substrate of silicon or the like. Note that the inspection target may be an electronic component such as a semiconductor chip, a chip size package (CSP), or a semiconductor element (integrated circuit (IC)) or another target on which electrical inspection is performed.

Further, the inspection apparatus is not limited to a semiconductor inspection apparatus and may be a substrate inspection apparatus that inspects a substrate, for example. The substrate that is an inspection target may be, for example, a substrate such as a print wiring substrate, a glass epoxy substrate, a flexible substrate, a ceramic multilayered wiring substrate, a package substrate for a semiconductor package, an interposer substrate, or a film carrier, an electrode panel for a display such as a liquid crystal display, an electro-luminescence (EL) display, or a touch panel display, an electrode panel for a touch panel, or substrates of various kinds.

The semiconductor inspection apparatus 1 illustrated in FIG. 1 includes an inspection portion 4, a sample platform 6, and an inspection processing unit 8. A placement portion 6a on which the semiconductor wafer 101 is placed is provided on an upper surface of the sample platform 6, and the sample platform 6 is configured to secure the semiconductor wafer 101 that is an inspection target at a predetermined position.

The placement portion 6a is adapted to be able to be lifted and lowered and is adapted such that the semiconductor wafer 101 accommodated in the sample platform 6 is caused to be lifted to an inspection position and the semiconductor wafer 101 after the inspection is stored in the sample platform 6, for example. Further, the placement portion 6a is adapted to be able to cause the semiconductor wafer 101 to rotate and orient an orientation flat to a predetermined direction, for example. Further, the semiconductor inspection apparatus 1 includes a transport mechanism such as a robot arm, which is not illustrated in the drawing. By the transport mechanism, the semiconductor wafer 101 is placed on the placement portion 6a, and the inspected semiconductor wafer 101 is transported from the placement portion 6a.

The inspection portion 4 includes an inspection jig 3, a pitch conversion block 35, and a connection plate 37. The inspection jig 3 is a jig for performing inspection by causing a plurality of probes Pr to contact with the semiconductor wafer 101, and for example, the inspection jig 3 is configured as what is called a probe card.

A plurality of chips is formed on the semiconductor wafer 101. A plurality of pads and inspection points such as bumps BP are formed in each of the chips. Corresponding to a partial region of the plurality of chips formed in the semiconductor wafer 101 (for example, the hatched region in FIG. 1; hereinafter, referred to as an inspection region), the inspection jig 3 holds a plurality of probes Pr such that the probes Pr correspond to the inspection points in the inspection region.

If the probes Pr have been caused to contact with the inspection points in the inspection region and the inspection in the inspection region is finished, the placement portion 6a lowers the semiconductor wafer 101, the sample platform 6 moves in parallel and causes the inspection region to move, the placement portion 6a causes the semiconductor wafer 101 to be lifted, and inspection is then performed by causing the probes Pr to contact with a new inspection region. In this manner, the entire semiconductor wafer 101 is inspected by performing the inspection while causing the inspection region to sequentially move.

Note that FIG. 1 is an explanatory diagram schematically and conceptually illustrating an example of the configuration of the semiconductor inspection apparatus 1 from the viewpoint of allowing easy understanding of the disclosure, and the number, the density, and the arrangement of the probes Pr, the shapes, and the ratio between the sizes of the inspection portion 4 and the sample platform 6, and the like are also illustrated in a simple and conceptual manner. For example, the inspection region is illustrated in an enlarged and emphasized manner as compared with a typical semiconductor inspection apparatus in terms of easy understanding of the arrangement of the probes Pr, and the inspection region may be smaller or larger.

The connection plate 37 is configured such that the pitch conversion block 35 can be detached and attached. A plurality of electrodes (not shown) that are connected to the pitch conversion block 35 are formed on the connection plate 37. The electrodes of the connection plate 37 are electrically connected to the inspection processing unit 8 by a cable, a connection terminals, or the like (not shown), for example. The pitch conversion block 35 is a pitch conversion member for converting an interval between the probes Pr into an electrode pitch of the connection plate 37.

The inspection jig 3 includes a plurality of the probes Pr (contact terminals) that have a tip portion P1 and a base end portion P2, which will be described later, and a support member 31 that holds a plurality of the probes Pr such that the tip portion P1 is oriented toward the semiconductor wafer 101.

An electrode 34a described later, which is brought into contact with and electrically conductive to the base end portion P2 of each of the probes Pr, is provided on the pitch conversion block 35. The inspection portion 4 includes a connection circuit (not shown) that electrically connects each of the probes Pr of the inspection jig 3 to the inspection processing unit 8 via the connection plate 37 and the pitch conversion block 35 and switches the connection.

In this manner, the inspection processing unit 8 is adapted to be able to supply an inspection signal to an optional one of the probes Pr and detects a signal from an optional one of the probes Pr via the connection plate 37 and the pitch conversion block 35.

The inspection processing unit 8 includes, for example, a power supply circuit, a voltmeter, an ammeter, a microcomputer, and so on. The inspection processing unit 8 controls a driving mechanism (not shown) to move and position the inspection portion 4, and brings each of the probes Pr into contact with each inspection point on the semiconductor wafer 101. In this manner, each inspection point is electrically connected to the inspection processing unit 8.

The inspection processing unit 8 supplies current or voltage for inspection to each inspection point on the semiconductor wafer 101 through each of the probes Pr of the inspection jig 3 in the above-described state, and executes inspection of the semiconductor wafer 101 for, for example, a disconnection in a circuit pattern, a short circuit, or the like on the basis of a voltage signal or a current signal obtained from each of the probes Pr. Alternatively, the inspection processing unit 8 may supply AC current or voltage to each inspection point, so as to measure an impedance of an inspection target on the basis of a voltage signal or a current signal obtained from each of the probes Pr.

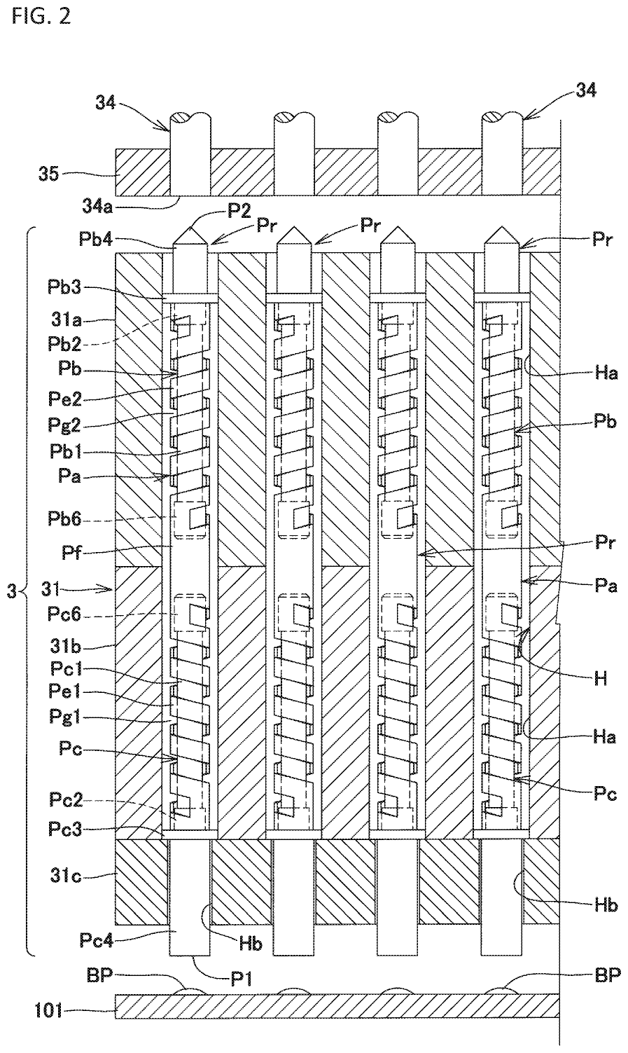

The support member 31 illustrated in FIG. 2 is composed of, for example, plate-shaped support plates 31a, 31b, and 31c stacked on each other. A plurality of through holes H penetrating the support plates 31a, 31b, and 31c are formed. The through hole H is a rectangular hole having a substantially square cross-sectional shape perpendicular to the axial direction.

In each of the support plates 31a and 31b, an insertion hole portion Ha having an opening hole of a predetermined diameter is formed. A support hole Hb having a smaller diameter than the insertion hole portion Ha is formed in the support plate 31c. The insertion hole portion Ha in the support plate 31a, the insertion hole portion Ha in the support plate 31b, and the support hole Hb in the support plate 31c communicate with each other to form the through hole H.

Note that, in place of the example in which the support plates 31a and 31b of the support member 31 are stacked on each other, the configuration may be such that the support plate 31a and the support plate 31b in a state of being separated from each other are connected by, for example, a support or the like. Further, without limitation to the example in which the support member 31 is composed of the plate-shaped support plates 31a, 31b, and 31c stacked on each other, the configuration may be such that the through hole H is provided in an integrated member.

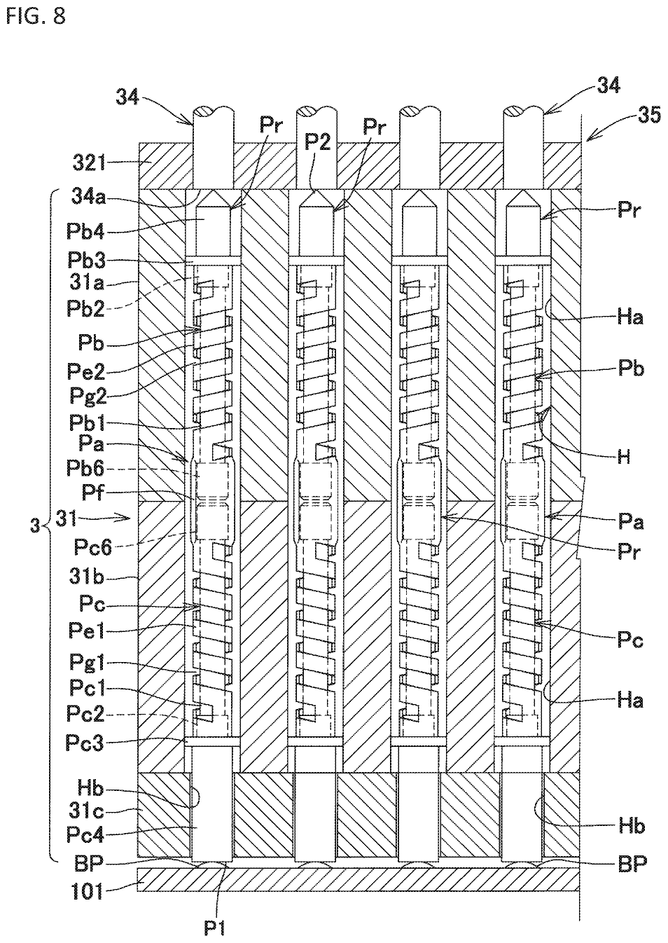

The pitch conversion block 35 made from, for example, an insulating resin material is attached to one end portion side of the support plate 31a, and an opening portion on one end portion side of the through hole H is blocked by the pitch conversion block 35 (see FIG. 8). A wiring 34 is attached to the pitch conversion block 35 so as to penetrate the pitch conversion block 35 at a position facing the opening portion of the through hole H.

A surface of the pitch conversion block 35 facing the support plate 31a is set to be flush with an end surface of the wiring 34. The end surface of the wiring 34 forms the electrode 34a. Each of the wirings 34 is connected to each electrode of the connection plate 37 while increasing a pitch. The pitch conversion block 35 may be configured using a multilayered wiring substrate such as a multi-layer organic (MLO) or a multi-layer ceramic (MLC) instead of the wiring 34.

The probe Pr is inserted into each of the through holes H of the support member 31. The probe Pr includes a tubular body Pa having conductivity and a tubular shape, and a second central conductor Pb and a first central conductor Pc having conductivity and a stick shape.

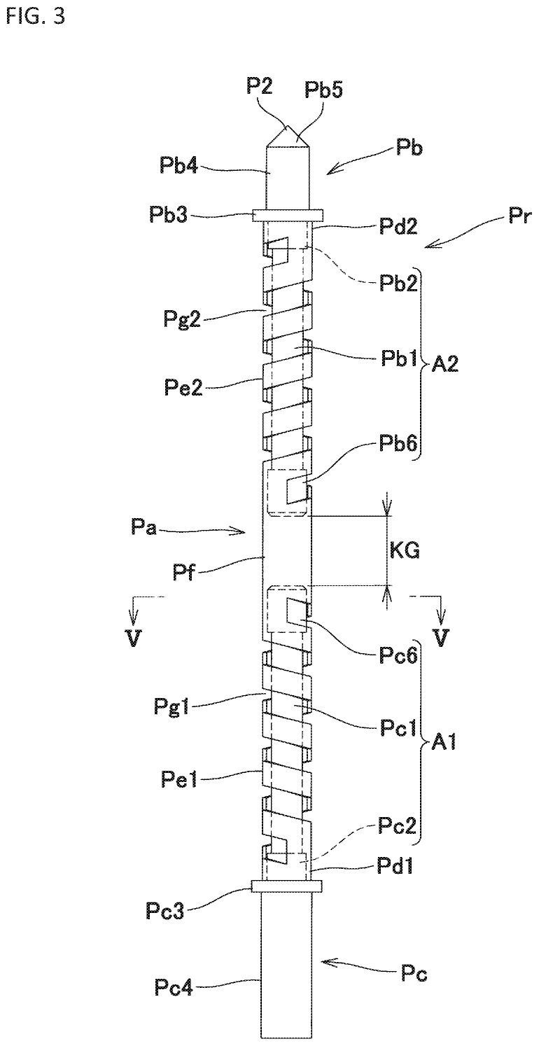

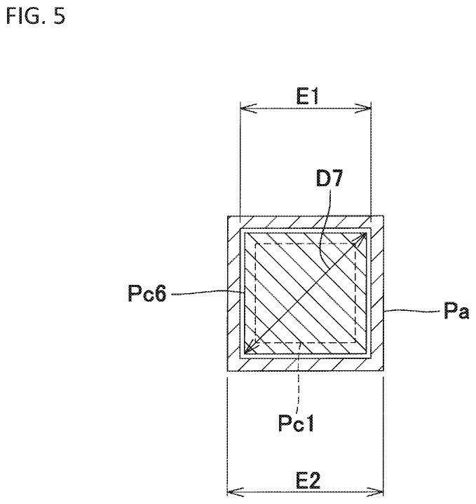

Referring to FIGS. 3 to 5, the tubular body Pa is a rectangular tube whose cross section perpendicular to the axial direction is a substantially square. For example, in the cross section of the tubular body Pa, an outer width E2 which is the length on the outer side of one side is about 25 to 300 μm, and an inner width E1 which is the length on the inner side of one side is about 10 to 250 μm, for example. As the tubular body Pa, for example, nickel or a nickel alloy can be used.

The tubular body Pa may be configured to have, for example, the outer width E2 of about 120 μm, the inner width E1 of about 100 μm, and the total length of about 1700 μm. Further, the structure may be such that an inner surface of the tubular body Pa is coated with a plating layer, such as, for example, a gold plating layer, and an outer surface of the tubular body Pa is applied with insulating coating as necessary. Further, a shape of the cross section perpendicular to the axial direction of the tubular body Pa may be substantially rectangular.

On both end portions of the tubular body Pa, a first tube end portion Pd1 and a second tube end portion Pd2 that clasp base end portions of a first stick-shaped body Pc1 and a second stick-shaped body Pb1 as described later are formed. Further, between the first tube end portion Pd1 and the second tube end portion Pd2, a first spring portion Pe1 and a second spring portion Pe2 that expand and contract in the axial direction of the tubular body Pa are formed over a predetermined length. Spiral winding directions of the first spring portion Pe1 and the second spring portion Pe2 are opposite to each other. Furthermore, a tube portion Pf that connects the first spring portion Pe1 and the second spring portion Pe2 to each other is provided in a central portion in the length direction of the tubular body Pa.

For example, a laser beam is emitted from a laser beam machine (not shown) onto a circumferential wall of the tubular body Pa to form a first helical groove Pg1 and a second helical groove Pg2, so that the first spring portion Pe1 and the second spring portion Pe2 that have a helical body extending along a peripheral surface of the tubular body Pa are configured. Then, the tubular body Pa is configured to be capable of expanding and contracting in the axial direction of the tubular body Pa through deformation of the first spring portion Pe1 and the second spring portion Pe2.

Note that the first spring portion Pe1 and the second spring portion Pe2 each having a helical body may be provided by, for example, performing etching on the circumferential wall of the tubular body Pa to form the first helical groove Pg1 and the second helical groove Pg2. Further, the structure may be such that the first spring portion Pe1 and the second spring portion Pe2 each having a helical body formed by, for example, electroforming are provided.

Further, the tubular body Pa provided with the first spring portion Pe1 and the second spring portion Pe2 may be formed by 3D printing. When 3D printing is used, it is preferable to form layers in a direction perpendicular to the axial direction of the tubular body Pa. The tubular body Pa, which has a rectangular cross-sectional shape, is easily manufactured by such 3D printing. Further, in a case where 3D printing is used, the entire probe Pr may be manufactured in a state where the first central conductor Pc and the second central conductor Pb are inserted into the tubular body Pa.

The tube portion Pf is composed of a circumferential wall portion of the tubular body Pa which is left by provision of a non-forming portion of the first helical groove Pg1 and the second helical groove Pg2 on the tubular body Pa, and is formed over a predetermined length in a central portion of the tubular body Pa. The first tube end portion Pd1 in which no spring portion is formed is formed in one end portion of the tubular body Pa, and the second tube end portion Pd2 in which no spring portion is formed is formed in the other end portion of the tubular body Pa.

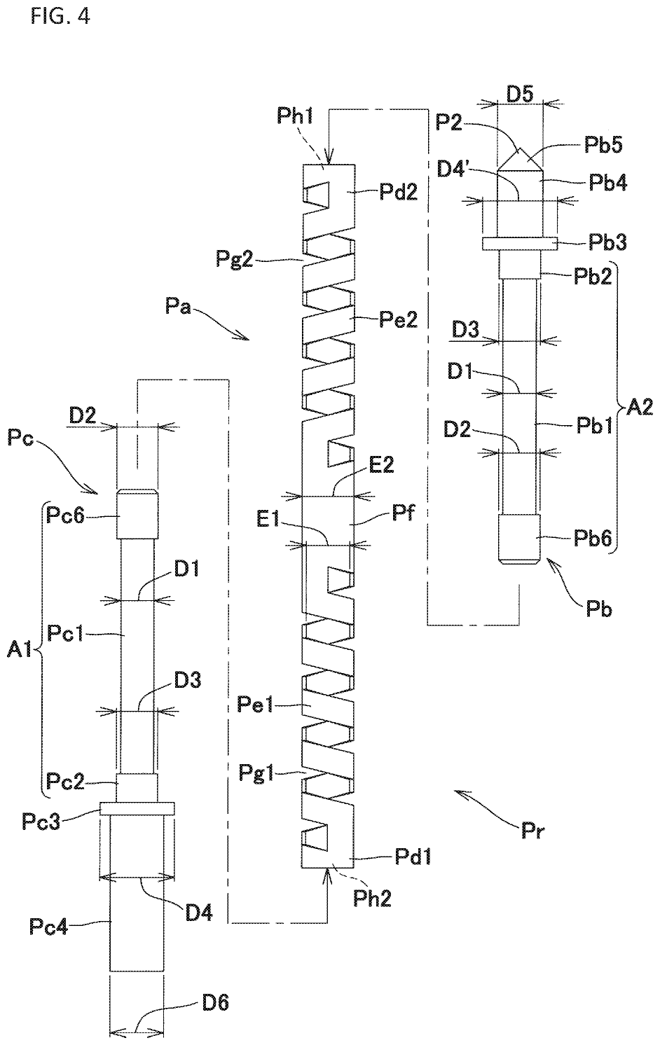

As shown in FIGS. 3 and 4, the first central conductor Pc includes the first stick-shaped body Pc1, which is inserted into one end portion of the tubular body Pa, a first clasped portion Pc2 provided in its base end portion, a collar portion Pc3 provided continuously with the first clasped portion Pc2, a first projecting portion Pc4 provided continuously with the collar portion Pc3, and a first swell portion Pc6 provided in a tip portion of the first stick-shaped body Pc1. The first stick-shaped body Pc1, the first clasped portion Pc2, and the first swell portion Pc6 correspond to an example of the first insertion portion.

The first projecting portion Pc4, the collar portion Pc3, the first clasped portion Pc2, the first stick-shaped body Pc1, and the first swell portion Pc6 have a rectangular shape having a substantially square cross-sectional shape perpendicular to the axial direction. Note that the cross-sectional shape of the first projecting portion Pc4, the collar portion Pc3, the first clasped portion Pc2, the first stick-shaped body Pc1, and the first swell portion Pc6 may be a rectangular shape different from a substantially square shape.

In the first stick-shaped body Pc1, an outside length D1 of one side in a cross section of the first stick-shaped body Pc1 is set to be smaller than the inner width E1 of the tubular body Pa so that the first stick-shaped body Pc1 can be easily inserted into the tubular body Pa. For example, in a case where the inner width E1 of the tubular body Pa is 100 μm, the outside length D1 of the first stick-shaped body Pc1 is 92 μm. Further, the first clasped portion Pc2, the first stick-shaped body Pc1, and the first swell portion Pc6 are configured to have such an axial length that the first swell portion Pc6 in a tip portion of the first central conductor Pc will be introduced into the tube portion Pf of the tubular body Pa when the first central conductor Pc is fitted to the tubular body Pa.

An outside length D2 of one side in a cross section of the first swell portion Pc6 is formed to be larger than the outside length D1 of the first stick-shaped body Pc1 and smaller than the inner width E1 of the tubular body Pa. Further, a difference between the outside diameter D2 of the first swell portion Pc6 and the inner width E1 of the tubular body Pa is set to be small to allow the tube portion Pf of the tubular body Pa to make slidable contact with the first swell portion Pc6 and a second swell portion Pb6 to establish electrical connection at the time of an inspection, which will be described below. For example, in a case where the outside length D1 of the first stick-shaped body Pc1 is 92 μm, and the inner width E1 of the tubular body Pa is 100 μm, the outside diameter D2 of the first swell portion Pc6 is 94 μm.

Further, a diagonal length D7 of a diagonal line in a cross section of the first swell portion Pc6 is longer than the inner width E1 of the tubular body Pa. In this manner, when the first central conductor Pc is about to rotate in the tubular body Pa, a corner portion of the first swell portion Pc6 interferes with an inner wall of the tubular body Pa, and the first swell portion Pc6 and the tubular body Pa come into contact with each other.

A width D3, which is a length of one side in the cross section of the first clasped portion Pc2, is set to be substantially the same as the inner width E1 of the tubular body Pa. As a result, when the first stick-shaped body Pc1 is inserted and fitted into the tubular body Pa, the first clasped portion Pc2 is press-fitted into the first tube end portion Pd1 and the first central conductor Pc is fitted in the tubular body Pa with an inner surface of the first tube end portion Pd1 being fixed to a peripheral surface of the first clasped portion Pc2 with pressure. Note that various connection methods such as caulking and welding can be used for connecting the first tube end portion Pd1 and the first clasped portion Pc2, and connecting the second tube end portion Pd2 and a second clasped portion Pb2.

In the collar portion Pc3 of the first central conductor Pc, a width D4 which is a length of one side in a cross section of the collar portion Pc3 is set to be larger than the inner width E1 of the tubular body Pa and to be larger than the width D3 of the first clasped portion Pc2. For example, in a case where the inner width E1 of the tubular body Pa is 100 μm, and the width D3 of the first clasped portion Pc2 is 103 μm, the width D4 of the collar portion Pc3 is 130 μm. In this manner, the collar portion Pc3 abuts on an end portion of the tubular body Pa to achieve positioning of the first stick-shaped body Pc1 when the first stick-shaped body Pc1 is inserted into the tubular body Pa to fit the first central conductor Pc.

Further, as shown in FIG. 2, the width D4 of the collar portion Pc3 is formed to be smaller than an inner width of the insertion hole portion Ha of the support member 31 to allow the support member 31 to support the probe Pr in a state where the tubular body Pa of the probe Pr is inserted in the insertion hole portion Ha.

The first projecting portion Pc4 of the first central conductor Pc is configured to be insertable into the support hole Hb by setting a width D6, which is a length of one side of a cross section of the first projecting portion Pc4, to be slightly smaller than the width D4 of the collar portion Pc3 and to be smaller than an inner width of the support hole Hb formed in the support plate 31c.

Further, the first projecting portion Pc4 is configured to have a total length greater than a thickness of the support plate 31c to allow an end portion of the first projecting portion Pc4 to protrude outwardly of the support member 31 from the support hole Hb in the support plate 31c in a state where the probe Pr is supported by the support member 31. Furthermore, a tip surface of the first projecting portion Pc4 is formed to be substantially flat. Note that a shape of the tip portion P1 of the first projecting portion Pc4 can be various shapes suitable for contact with the inspection point, such as a crown shape and a conical shape.

In contrast, the second central conductor Pb includes the first swell portion Pc6 of the first central conductor Pc, the first stick-shaped body Pc1, the second swell portion Pb6 which has the same shape and outside diameter as those of the first clasped portion Pc2, the second stick-shaped body Pb1, and the second clasped portion Pb2. A collar portion Pb3 is provided in a base end portion of the second stick-shaped body Pb1. The collar portion Pb3 has a width D4′ greater than that of the second clasped portion Pb2 and at the same extent as that of the collar portion Pc3 of the first central conductor Pc. The width D4′ is, for example, about 130 μm.

A second projecting portion Pb4 of the second central conductor Pb is configured to be insertable into the insertion hole portion Ha by setting a width D5, which is a length of one side of a cross section of the second projecting portion Pb4, to be slightly smaller than the width D4′ of the collar portion Pb3 and to be smaller than an inner width of the insertion hole portion Ha formed in the support plate 31a.

Further, a tapered inclined portion Pb5 is formed in a tip portion of the second projecting portion Pb4, and a tip surface of the inclined portion Pb5 abuts on the electrode 34a provided on the pitch conversion block 35 at the time of inspection of the semiconductor wafer 101 described later or the like.

Further, the first stick-shaped body Pc1, the second stick-shaped body Pb1, and so on are configured to have such total lengths that a predetermined gap KG will be created between a tip surface of the first swell portion Pc6 and a tip surface of the second swell portion Pb6 as illustrated in FIG. 3 in a state where the first central conductor Pc and the second central conductor Pb are fitted into the tubular body Pa.

Furthermore, the first stick-shaped body Pc1, the second stick-shaped body Pb1, and so on are configured to have such axial lengths that a tip surface of the first swell portion Pc6 and a tip surface of the second swell portion Pb6 will be kept opposite to each other with a predetermined gap between them even when each of the first projecting portion Pc4 and the second projecting portion Pb4 is pressed into the support member 31 (see FIG. 8) at the time of inspection, which will be described later.

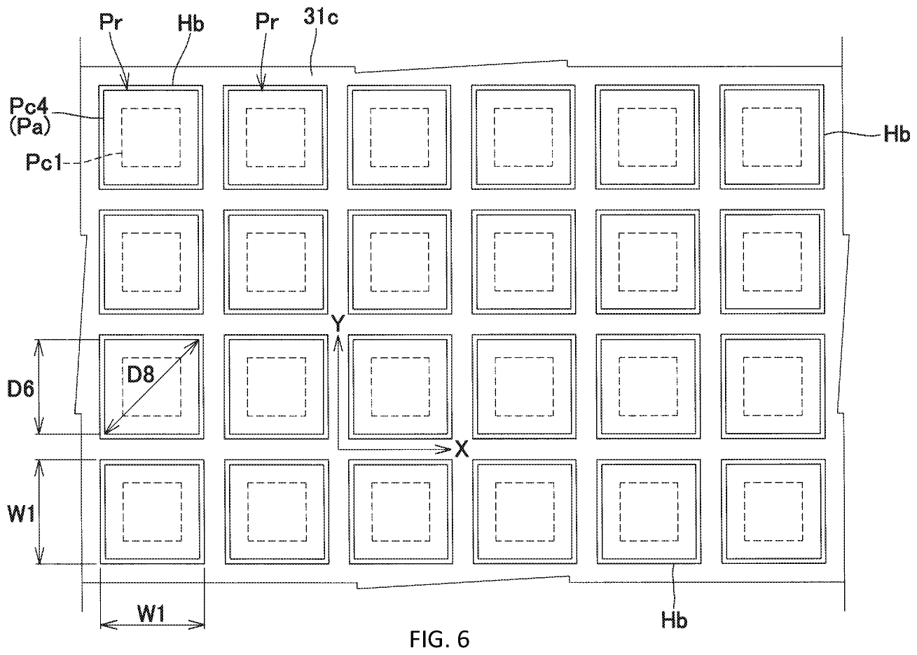

As illustrated in FIG. 6, a plurality of the support holes Hb are formed at positions corresponding to intersections of a grid on the support plate 31c. Then, the probe Pr is held in each of the support holes Hb.

Each of the through holes H is disposed such that one side of a rectangular opening portion of each of the through holes H extends along a first direction X and the other side continuous with the one side extends along a second direction Y perpendicular to the first direction X. A width W1 of a side of the opening portion of the through hole H is slightly larger than the width D6 of the first projecting portion Pc4 and smaller than a diagonal length D8 that is the length of a diagonal line of the first projecting portion Pc4. Therefore, the direction of a side of the cross section of the probe Pr in the through hole H is regulated by the direction of a side of an inner wall of the through hole H. As a result, directions of sides of a cross section of the tubular body Pa are also arranged depending on the directions of the sides of the inner wall of the through hole H, such that longitudinal sides and lateral sides are along the same directions.

Note that a plurality of the probes Pr only need to be arranged such that the longitudinal sides and the lateral sides are along the same directions, and are not necessarily limited to an example in which the probes Pr are arranged at positions corresponding to intersections of a grid.

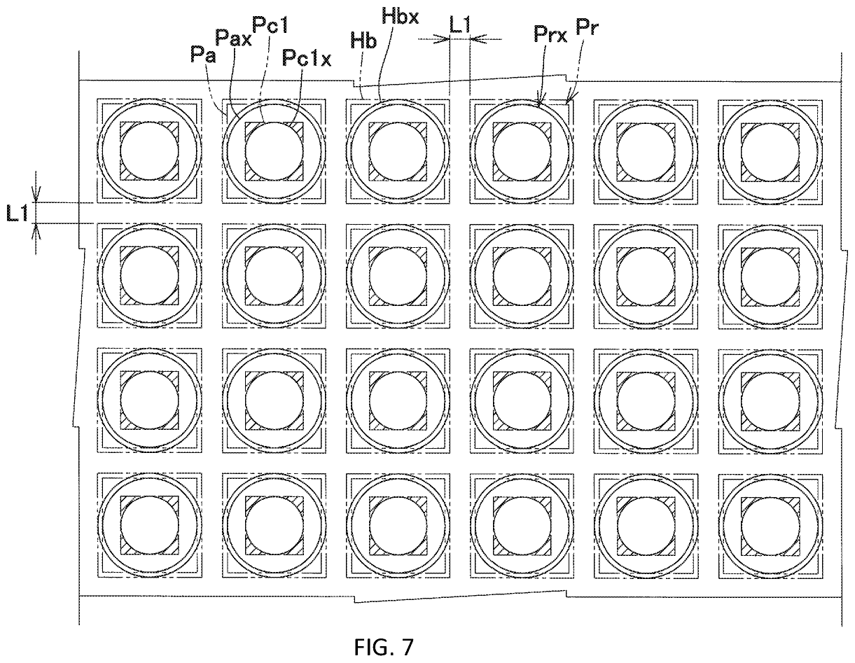

FIG. 7 illustrates a state in which a probe Prx in which a columnar first stick-shaped body Pc1x is inserted into a cylindrical tubular body Pax described in JP 2007-24664 A is inserted into a circular support hole Hbx arranged in a grid shape. In FIG. 7, the support hole Hb, the probe Pr, the tubular body Pa, and the first stick-shaped body Pc1 illustrated in FIG. 6 are shown by a one-dot chain line in an overlapping manner. Further, a difference between a cross section of the first stick-shaped body Pc1 and a cross section of the first stick-shaped body Pc1x is indicated by hatching with oblique lines.

An adjacent interval between the support holes Hbx illustrated in FIG. 7 is an interval L1, and an adjacent interval between the support holes Hb is the same interval L1. From FIG. 7, it can be seen that the cross-sectional area of the probe Pr having a rectangular cross section is larger than that of the first stick-shaped body Pc1x having a circular cross section even in a case where adjacent intervals between the support holes and the probes are equal between the probe Prx having a circular cross section and the probe Pr having a rectangular cross section. When the cross-sectional area is large, a resistance value of the probe Pr becomes small.

Therefore, according to the probe Pr and the inspection jig 3 using the probe Pr, it is easy to make the adjacent pitch small while reducing an increase in the resistance value.

In a state before the inspection jig 3 is attached to the pitch conversion block 35, as illustrated in FIG. 2, the second projecting portion Pb4 slightly projects from the support plate 31a. Then, as illustrated in FIG. 8, when one end portion side (upper side of FIGS. 2 and 8) of the support plate 31a is attached to the pitch conversion block 35, an upper end of the second projecting portion Pb4, that is, the base end portion P2 of the probe Pr comes into contact with the electrode 34a of the pitch conversion block 35 and is pressed toward the support member 31 side.

As a result, the first spring portion Pe1 and the second spring portion Pe2 of the tubular body Pa are compressed and elastically deformed, and thus, a projecting portion of the second projecting portion Pb4 is pressed into the support member 31 against a biasing force of the first spring portion Pe1 and the second spring portion Pe2. Then, a tip of the second projecting portion Pb4, that is, the base end portion P2 of the probe Pr, is pressed against the electrode 34a in accordance with the biasing force of the first spring portion Pe1 and the second spring portion Pe2, so that one end portion of the probe Pr and the electrode 34a are kept in a stable conductive contact state.

Note that it is not always necessary to form the tapered inclined portion Pb5 in an upper end portion of the second projecting portion Pb4, and an upper end surface of the second projecting portion Pb4 may be formed into a flat surface, and a tip shape of the second projecting portion Pb4 can be formed into various shapes suitable for contact with the electrode 34a.

When the inspection jig 3 is pressed against the semiconductor wafer 101, the first projecting portion Pc4 of the first central conductor Pc comes into contact with the bump BP of the semiconductor wafer 101 and is pressed toward the support member 31 side.

As a result, the first spring portion Pe1 and the second spring portion Pe2 of the tubular body Pa are further compressed and elastically deformed, and thus, a projecting portion of the first projecting portion Pc4 is pressed into the support member 31 against a biasing force of the first spring portion Pe1 and the second spring portion Pe2. Then, the tip portion P1 of the first projecting portion Pc4 is pressed against the bump BP of the semiconductor wafer 101 according to the biasing force of the first spring portion Pe1 and the second spring portion Pe2. In this manner, the tip portion P1 of the first projecting portion Pc4 and the inspection point (bump BP) of the semiconductor wafer 101 are held in a stable conductive contact state.

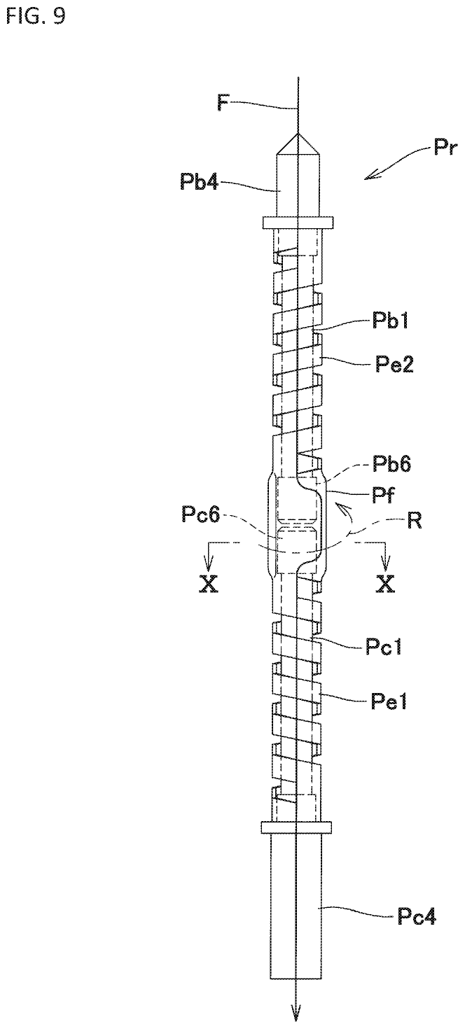

Referring to FIG. 9, when the first spring portion Pe1 and the second spring portion Pe2 are compressed, the first spring portion Pe1 and the second spring portion Pe2 generate rotational forces corresponding to winding directions of spirals. Since the winding directions of the spirals of the first spring portion Pe1 and the second spring portion Pe2 are opposite to each other, the first spring portion Pe1 and the second spring portion Pe2 generate rotational forces in opposite directions to each other.

As a result, the tube portion Pf between the first spring portion Pe1 and the second spring portion Pe2 rotates in a rotation direction R illustrated in FIG. 9.

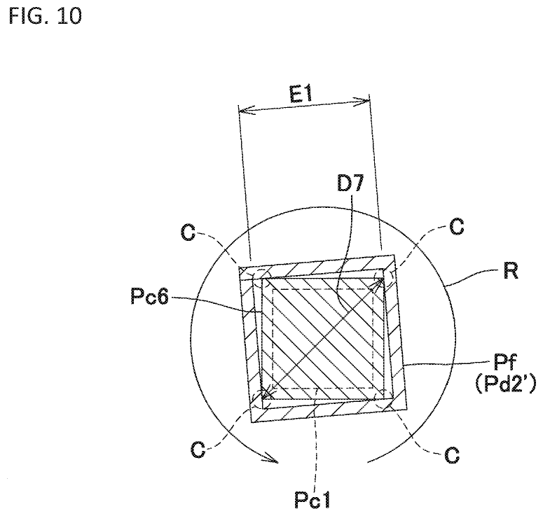

As illustrated in FIG. 10, the diagonal length D7 of the first swell portion Pc6 located in the tube portion Pf is longer than the inner width E1 of the tubular body Pa, that is, the inner width E1 of the tube portion Pf. For this reason, when the tube portion Pf rotates, a corner portion C of the first swell portion Pc6 of the first central conductor Pc abuts on an inner wall of the tube portion Pf.

Similarly, when the tube portion Pf rotates, a corner portion of the second swell portion Pb6 of the second central conductor Pb also abuts on the inner wall of the tube portion Pf. As a result, when the probe Pr is pressed against the bump BP, the reliability of bringing the first swell portion Pc6 and the second swell portion Pb6 into conductive contact with the inner wall of the tube portion Pf is improved.

In a case where the contact of the first swell portion Pc6 and the second swell portion Pb6 with the inner wall of the tube portion Pf is insufficient, an electric resistance between the tip portion P1 and the base end portion P2 of the probe Pr increases.

However, in the probe Pr described above, the first spring portion Pe1 and the second spring portion Pe2 are compressed when the tip portion P1 of the first projecting portion Pc4 is pressed against the bump BP, and the tube portion Pf is rotated by the rotational force generated by the compression. As a result, the reliability of bringing the first swell portion Pc6 and the second swell portion Pb6 into conductive contact with the inner wall of the tube portion Pf is improved. When the reliability that the first swell portion Pc6 and the second swell portion Pb6 are brought into conductive contact with the inner wall of the tube portion Pf increases, the possibility that a contact resistance between the first swell portion Pc6 and the second swell portion Pb6 and the tube portion Pf increases due to a contact failure decreases. As a result, the possibility of an increase in a resistance value of a current path F (FIG. 9) of inspection current from the second projecting portion Pb4 to the first projecting portion Pc4 via the second stick-shaped body Pb1, the second swell portion Pb6, the tube portion Pf, the first swell portion Pc6, and the first stick-shaped body Pc1 is reduced. That is, the possibility of an increase in a resistance value of the probe Pr can be reduced.

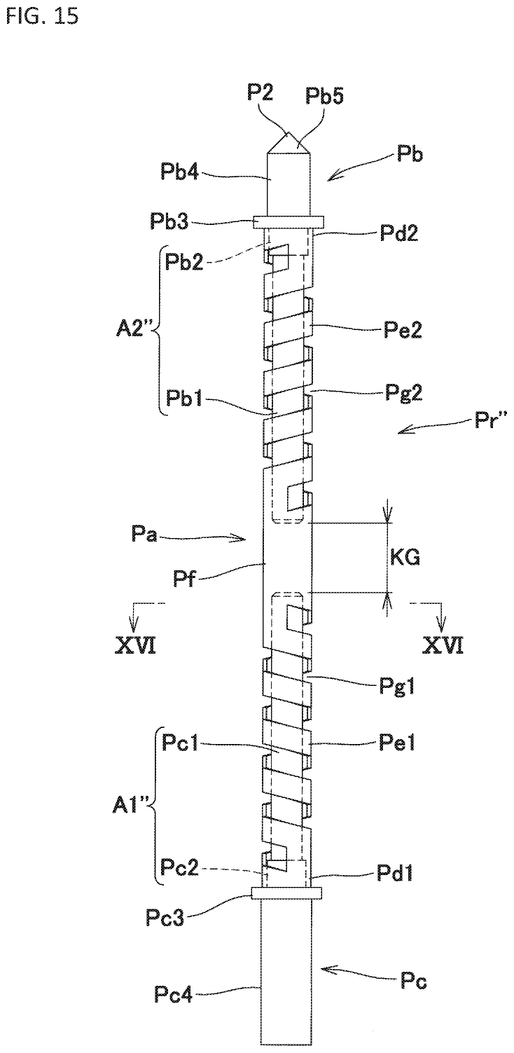

Note that the configuration may be such that, as illustrated in FIG. 15, the first central conductor Pc and the second central conductor Pb do not include the first swell portion Pc6 or the second swell portion Pb6, and the lengths of the first stick-shaped body Pc1 and the second stick-shaped body Pb1 are set such that the length of a diagonal line in the cross section of the first stick-shaped body Pc1 and the second stick-shaped body Pb1 is larger than the inner width E1 of the tubular body Pa and the tip portions of the first stick-shaped body Pc1 and the second stick-shaped body Pb1 are located in the tube portion Pf.

Even with such a configuration, in a case where the tube portion Pf rotates, the first stick-shaped body Pc1 and the second stick-shaped body Pb1 abut on and are brought into conductive contact with the inner wall of the tube portion Pf, so that an effect of reducing the possibility of an increase in the resistance value and the inductance of the probe Pr can be obtained.

However, by providing the first swell portion Pc6 and the second swell portion Pb6 in the first central conductor Pc and the second central conductor Pb, and making the first stick-shaped body Pc1 and the second stick-shaped body Pb1 thinner than the first swell portion Pc6 and the second swell portion Pb6, the possibility that the first stick-shaped body Pc1 and the second stick-shaped body Pb1 come into contact with the first spring portion Pe1 and the second spring portion Pe2 is reduced.

As a result, the possibility that inspection current partially flows from the first stick-shaped body Pc1 and the second stick-shaped body Pb1 to the first spring portion Pe1 and the second spring portion Pe2 or friction occurs between the first stick-shaped body Pc1 and the second stick-shaped body Pb1 and the first spring portion Pe1 and the second spring portion Pe2 is reduced. Therefore, it is more preferable to provide the first swell portion Pc6 and the second swell portion Pb6 on the first central conductor Pc and the second central conductor Pb.

Further, by making the winding directions of the spirals of the first spring portion Pe1 and the second spring portion Pe2 opposite to each other, the rotation due to compression of the first spring portion Pe1 is offset by the rotation due to compression of the second spring portion Pe2 between the first projecting portion Pc4 and the second projecting portion Pb4. Therefore, the rotational movement of the first projecting portion Pc4 and the second projecting portion Pb4 is reduced. In particular, in a case where the winding directions of the spirals are made opposite to each other and the numbers of turns are made the same between the first spring portion Pe1 and the second spring portion Pe2, the first projecting portion Pc4 and the second projecting portion Pb4 are in a substantially stationary state. As a result, the contact stability of the probe Pr with respect to the bump BP and the electrode 34a is improved.

Note that, in the first spring portion Pe1 and the second spring portion Pe2, the winding directions of the spirals may be the same. When the winding directions of the spirals are the same, the first helical groove Pg1 and the second helical groove Pg2 only need to be cut in the same direction, so that machining is facilitated, and thus the first spring portion Pe1 and the second spring portion Pe2 are easily manufactured.

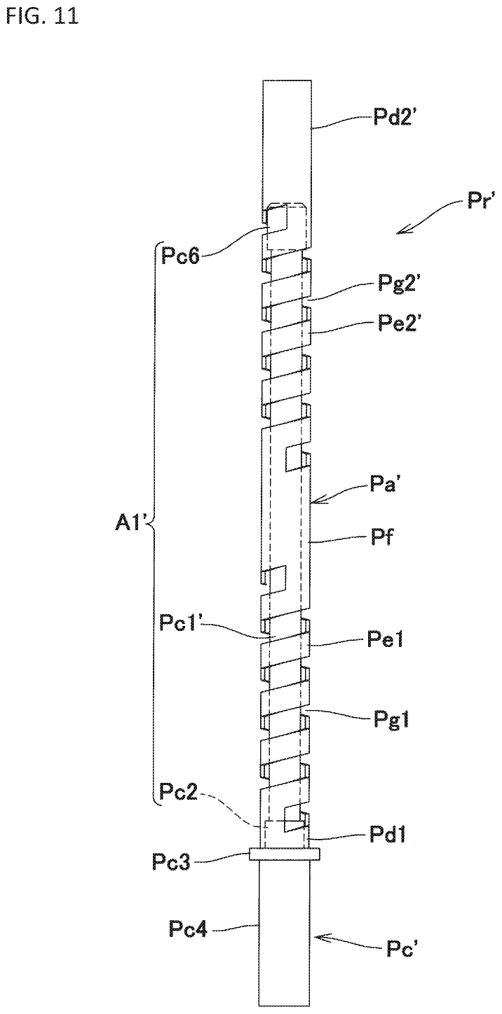

A probe Pr′ illustrated in FIG. 11 is different from the probe Pr illustrated in FIG. 3 in that the probe Pr does not include the second central conductor Pb, and the winding directions of spirals of the first spring portion Pe1 and a second spring portion Pe2′ are the same direction. Since the probe Pr′ is configured similarly to the probe Pr in other points, characteristic points of the probe Pr′ will be described below.

The probe Pr′ is used in place of the probe Pr in the inspection jig 3 illustrated in FIGS. 2 and 8.

A tubular body Pa′ includes a second spring portion Pe2′ instead of the second spring portion Pe2. In the second spring portion Pe2′ and the first spring portion Pe1, winding directions of spirals are the same. Further, a second tube end portion Pd2′ of the tubular body Pa′ is longer than the second tube end portion Pd2 and is inserted into the insertion hole portion Ha in the inspection jig 3 illustrated in FIGS. 2 and 8. In a state where the inspection jig 3 is not attached to the pitch conversion block 35, a tip portion of the second tube end portion Pd2′ projects from the support plate 31a.

Then, when the inspection jig 3 is attached to the pitch conversion block 35, a tip portion of the second tube end portion Pd2′ abuts on the electrode 34a.

A first central conductor Pc′ is different from the first central conductor Pc in the length of a first stick-shaped body Pc1′. The first stick-shaped body Pc1′ is longer than the first stick-shaped body Pc1. The length of the first stick-shaped body Pc1′ is set such that the first swell portion Pc6 is located in the second tube end portion Pd2′. The second tube end portion Pd2′ corresponds to an example of the tube portion.

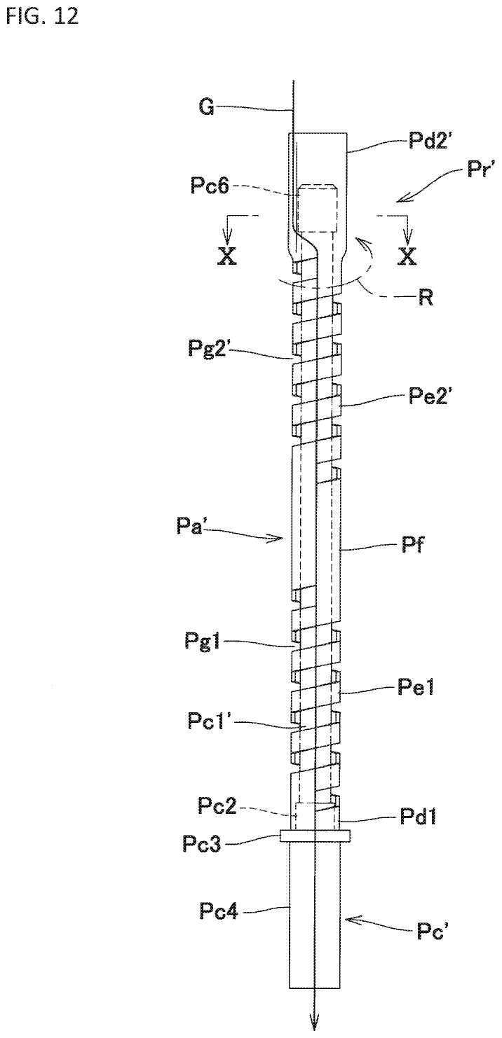

Referring to FIG. 12, when the first spring portion Pe1 and the second spring portion Pe2′ are compressed, the first spring portion Pe1 and the second spring portion Pe2′ generate rotational forces corresponding to winding directions of spirals. Since the winding directions of the spirals of the first spring portion Pe1 and the second spring portion Pe2′ are the same, the first spring portion Pe1 and the second spring portion Pe2′ generate rotational forces in the same direction.

Since the tubular body Pa′ and the first central conductor Pc′ are fixed by the first tube end portion Pd1 and the first clasped portion Pc2, the rotation amount of the tubular body Pa′ generated by the first spring portion Pe1 and the second spring portion Pe2′ increases as it goes away from the first tube end portion Pd1, and becomes maximum in the second tube end portion Pd2′.

Then, since the first swell portion Pc6 is located in the second tube end portion Pd2′ having the maximum rotation amount, the first swell portion Pc6 abuts on an inner wall of the second tube end portion Pd2′ as illustrated in parentheses in FIG. 10. When the second tube end portion Pd2′ and the first swell portion Pc6 are in conductive contact with each other, inspection current used for the inspection reaches the first projecting portion Pc4 via the second tube end portion Pd2′, the first swell portion Pc6, and the first stick-shaped body Pc1′ as illustrated as a current path G in FIG. 12. Therefore, the inspection current does not flow through the first spring portion Pe1 and the second spring portion Pe2′.

If the inspection current does not flow through the first spring portion Pe1 and the second spring portion Pe2′, it is possible to reduce the possibility that the resistance value and the inductance of the probe Pr′ increase, similarly to the probe Pr.

Note that, as in the case of the probe Pr, the configuration may be such that the first central conductor Pc′ does not include the first swell portion Pc6, and the length of the first stick-shaped body Pc1′ is set such that the length of a diagonal line in a cross section of the first stick-shaped body Pc1′ is larger than the inner width E1 of the tubular body Pa′ and a tip portion of the first stick-shaped body Pc1′ is located in the second tube end portion Pd2′.

Even with such a configuration, in a case where the second tube end portion Pd2′ rotates, the first stick-shaped body Pc1′ abuts on and is brought into conductive contact with the inner wall of the second tube end portion Pd2′, so that an effect of reducing the possibility of an increase in the resistance value and the inductance of the probe Pr′ can be obtained.

However, by providing the first swell portion Pc6 in the first central conductor Pc′ and making the first stick-shaped body Pc1′ thinner than the first swell portion Pc6, the possibility that the first stick-shaped body Pc1′ comes into contact with the first spring portion Pe1 and the second spring portion Pe2′ is reduced.

As a result, the possibility that inspection current partially flows from the first stick-shaped body Pc1′ to the first spring portion Pe1 and the second spring portion Pe2′ or friction occurs between the first stick-shaped body Pc1′ and the first spring portion Pe1 and the second spring portion Pe2′ is reduced. Therefore, it is more preferable to provide the first swell portion Pc6 on the first central conductor Pc′.

Note that the tubular body Pa′ does not need to include the tube portion Pf, and the first spring portion Pe1 and the second spring portion Pe2′ may be a series of spring portions.

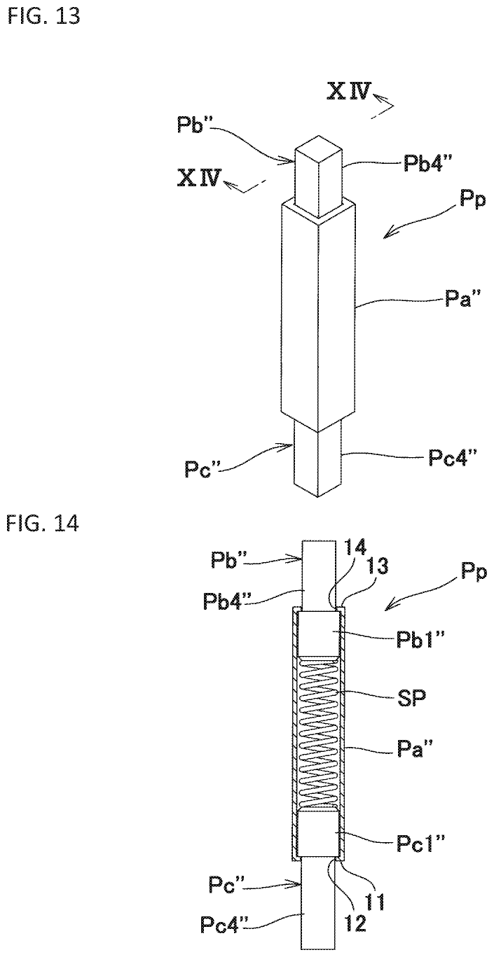

A pogo pin Pp illustrated in FIGS. 13 and 14 corresponds to an example of the contact terminal.

The pogo pin Pp can be used as a probe instead of the probe Pr. Further, the pogo pin Pp can be used as a contact such as a pin or a connection pin of a connector.

The pogo pin Pp illustrated in FIGS. 13 and 14 includes a tubular body Pa″ having conductivity and a tubular shape, a first central conductor Pc″ having conductivity and a stick shape, a second central conductor Pb″ having conductivity, and a spring SP (biasing member) provided in the tubular body Pa″ and biasing the first central conductor Pc″ in a direction projecting from the tubular body Pa″.

The tubular body Pa″ has a rectangular cross section perpendicular to the axial direction. An engagement protrusion 11 protruding inward from the inner periphery of the tubular body Pa″ is formed in one end portion of the tubular body Pa″. An opening portion 12 is formed by a tip portion of the engagement protrusion 11. An engagement protrusion 13 protruding inward from the inner periphery of the tubular body Pa″ is formed in the other end portion of the tubular body Pa″. An opening portion 14 is formed by a tip portion of the engagement protrusion 13.

The first central conductor Pc″ includes a first stick-shaped body Pc1″ (first insertion portion) inserted into the tubular body Pa″ and a first projecting portion Pc4″ projecting from one end portion of the tubular body Pa″. The first central conductor Pc″, that is, the first stick-shaped body Pc1″ and the first projecting portion Pc4″ have a rectangular cross section perpendicular to the axial direction.

The first stick-shaped body Pc1″ is disposed inside the tubular body Pa″. The first projecting portion Pc4″ is inserted into the opening portion 12, has one end connected to the first stick-shaped body Pc1 and the other end projecting from the opening portion 12. One side of the cross section perpendicular to the axial direction of the first stick-shaped body Pc1″ is longer than one side of the opening portion 12. In this manner, the first stick-shaped body Pc1″ interferes with the engagement protrusion 11, and the first central conductor Pc″ is prevented from coming out of the tubular body Pa″.

The second central conductor Pb″ includes a second insertion portion Pb1″ inserted into the tubular body Pa″ and a second projecting portion Pb4″ projecting from one end portion of the tubular body Pa″. The second central conductor Pb″, that is, the second insertion portion Pb1″ and the second projecting portion Pb4″ have a rectangular cross section perpendicular to the axial direction.

The second insertion portion Pb1″ is disposed inside the tubular body Pa″. The second projecting portion Pb4″ is inserted into the opening portion 14, has one end connected to the second insertion portion Pb1″ and the other end projecting from the opening portion 14. One side of the cross section perpendicular to the axial direction of the second insertion portion Pb1″ is longer than one side of the opening portion 14. In this manner, the second insertion portion Pb1″ interferes with the engagement protrusion 13, and the second central conductor Pb″ is prevented from coming out of the tubular body Pa″.

The spring SP is arranged between the first stick-shaped body Pc1″ and the second insertion portion Pb1″ in the tubular body Pa″. The spring SP biases the first central conductor Pc″ and the second central conductor Pb″ in a direction away from each other. Note that the configuration may be such that the pogo pin Pp does not include the second central conductor Pb″ and the opening portion 14 is closed.

In a case where, similarly to the probe Pr illustrated in FIG. 6, a plurality of the pogo pins Pp configured as described above are inserted into the through holes H arranged such that one side of a rectangular opening portion extends along the first direction X and another side continuous with the one side extends along the second direction Y perpendicular to the first direction X, the cross-sectional area of the conductor can be increased as compared with the columnar probe according to JP 2007-24664 A, similarly to the probe Pr illustrated in FIG. 7. Therefore, according to the pogo pin Pp and the inspection jig using the pogo pin Pp, it is easy to make the adjacent pitch small while reducing an increase in the resistance value.

Note that the tubular bodies Pa, Pa′, Pa″, the first stick-shaped bodies Pc1, Pc1′, Pc1″, the first swell portion Pc6, and the second stick-shaped bodies Pb1, Pb1′, Pb1″ may have a hexagonal cross-sectional shape perpendicular to the axial direction. As an example, FIG. 16 illustrates a cross-sectional view of a tubular body Pa′″, a first stick-shaped body Pc1′″, and a first swell portion Pc6′″ having a hexagonal cross-sectional shape.

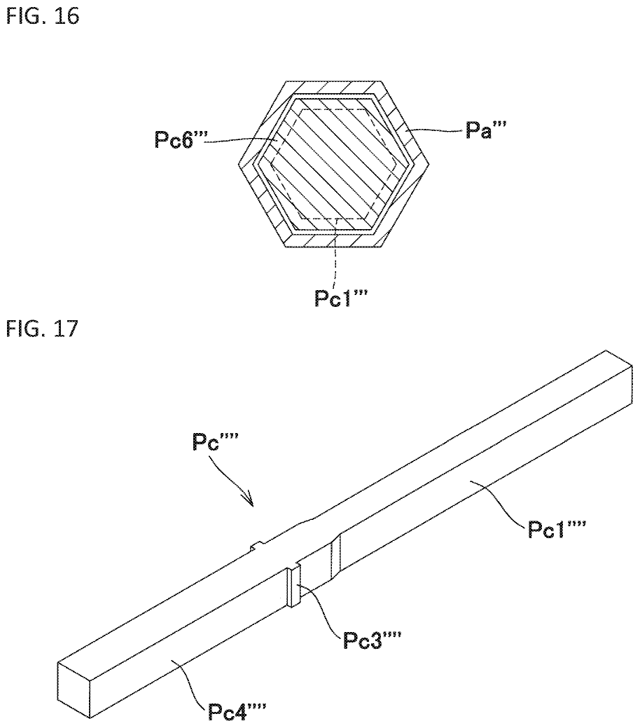

Further, the first central conductors Pc and Pc′ may be configured such that a collar portions Pc3′″ projects only from a pair of outer wall surfaces facing each other in a first projecting portion Pc4″″ and is not provided on the other pair of outer wall surfaces like a first central conductor Pc″″ illustrated in FIG. 17.

That is, the contact terminal according to an example of the present disclosure includes a tubular body having conductivity and a tubular shape, and a first central conductor having conductivity and a stick shape. The tubular body has a cross section perpendicular to an axial direction, the cross section having a shape that is rectangular or hexagonal, and the first central conductor includes a first insertion portion having a cross section perpendicular to an axial direction of the first central conductor, the cross section having a shape that is the same as the shape of the cross section of the tubular body, the first insertion portion being inserted into one end portion side of the tubular body, and a first projecting portion projecting from one end portion of the tubular body.

According to this configuration, the tubular body and the first central conductor have a rectangular or hexagonal cross section perpendicular to the axial direction. As a result, even in a case where a distance between adjacent contact terminals is equal to that in the probe having a circular cross section as described in the background art, the cross-sectional area of the first central conductor is larger than that of the probe having a circular cross section, and the resistance value of the contact terminal is smaller.

Further, a length of a diagonal line in the cross section of the first insertion portion is preferably larger than that of one side of an inner wall in the cross section of the tubular body.

According to this configuration, when the tubular body and the first insertion portion rotate relative to each other, an inner wall of the tubular body and a corner portion of the first insertion part interfere with each other, so that the reliability of electrically connecting the tubular body and the first insertion portion is improved.

Further, it is preferable to include a second central conductor having conductivity and a stick shape. The second central conductor preferably includes a second insertion portion having a cross section perpendicular to an axial direction of the second central conductor, the cross section having a shape that is same as the shape of the cross section of the tubular body, the second insertion portion being inserted into the other end portion side of the tubular body, and a second projecting portion projecting from the other end portion of the tubular body, the tubular body preferably includes a first spring portion that has a spiral shape and biases the first projecting portion in the projecting direction, a tube portion connected to the first spring portion, and a second spring portion that has a spiral shape and is connected to a side of the tube portion opposite to the first spring portion, and the first spring portion and the second spring portion preferably have spiral winding directions opposite to each other.

According to this configuration, when the contact terminal abuts on an object and the first spring portion and the second spring portion are compressed, the first spring portion and the second spring portion generate a rotational force corresponding to the winding directions of the spirals. Since the winding directions of the spirals of the first spring portion and the second spring portion are opposite to each other, the first spring portion and the second spring portion generate rotational forces of opposite rotations. As a result, the tube portion between the first spring portion and the second spring portion rotates. The rotation of the tube portion improves the reliability of bringing the first and second central conductors into contact with the inner wall of the tube portion.

Further, the first insertion portion preferably includes a first swell portion provided in an end portion on an opposite side to the first projecting portion, and a first stick-shaped body that extends from the first swell portion toward the first projecting portion and is thinner than the first swell portion.

According to this configuration, an end portion of the first insertion portion becomes the first swell portion that is thick, and the first stick-shaped body between the first swell portion and the first projecting portion becomes thin. As a result, the first stick-shaped body is less likely to come into contact with the tubular body in a section from the first projecting portion to the first swell portion, so that friction between the first stick-shaped body and the tubular body can be reduced, and the reliability of conductive contact between the first swell portion and the tubular body can be improved.

Further, the first swell portion is preferably located in the tube portion.

According to this configuration, the first projecting portion can be brought into elastic contact with an object. Further, the first swell portion comes into contact with the inner wall of the tube portion where the spring is not formed. As a result, the possibility that current flowing through the contact terminal flows through the spring portion is reduced.

Further, the second insertion portion preferably includes a second swell portion provided in an end portion on an opposite side to the second projecting portion, and a second stick-shaped body that extends from the second swell portion toward the second projecting portion and is thinner than the second swell portion.

According to this configuration, an end portion of the second insertion portion becomes the second swell portion that is thick, and the second stick-shaped body between the second swell portion and the second projecting portion becomes thin. As a result, the second stick-shaped body is less likely to come into contact with the tubular body in a section from the second projecting portion to the second swell portion, so that friction between the second stick-shaped body and the tubular body can be reduced, and the reliability of conductive contact between the second swell portion and the tubular body can be improved.

Further, the first swell portion and the second swell portion are preferably located in the tube portion.

According to this configuration, the first swell portion and the second swell portion come into contact with the inner wall of the tube portion of the tubular body. As a result, since current flowing through the contact terminal flows through the first stick-shaped body, the tube portion, and the second stick-shaped body and does not flow through the spring portion, it is possible to reduce the possibility that the resistance value of the contact terminal increases due to the spring portion.

Further, the tubular body may include a spring portion that has a spiral shape and biases the first projecting portion in the projecting direction, and the spring portion preferably has the spiral winding direction that is constant.

In a case where the tube portion is provided in the end portion of the tubular body, the rotation amount of the tube portion becomes large as the winding direction of the spring portion is constant. As a result, the reliability of the conductive contact between the inner wall of the tube portion and the first swell portion increases.

Further, it is preferable to further include a biasing member that is provided in the tubular body and biases the first central conductor toward the one end portion side.

According to this configuration, the first central conductor projects toward one end portion side by the biasing force of the biasing member in the tubular body. This contact terminal constitutes what is called a pogo pin.

Further, an inspection jig according to an example of the present disclosure includes a plurality of the contact terminals described above and a support member that supports a plurality of the contact terminals.

According to this configuration, the inspection jig including a plurality of the contact terminals is obtained.

Further, the support member preferably supports sides in the shape of the cross section of the tubular body of a plurality of the contact terminals in the same direction.

According to this configuration, it is easy to reduce the adjacent pitch of a plurality of the contact terminals.

Further, an inspection apparatus according to an example of the present disclosure includes the inspection jig described above and an inspection processing unit that performs an inspection of an inspection target on the basis of an electrical signal obtained by bringing the contact terminal into contact with an inspection point provided on the inspection target.

According to this configuration, it is easy to reduce the adjacent pitch of the contact terminals while reducing an increase in the resistance value of the contact terminals used for inspection.

In the contact terminal, the inspection jig, and the inspection apparatus having such a configuration, it is easy to reduce the adjacent pitch of the contact terminals while reducing an increase in the resistance value.

This application is based on Japanese Patent Application No. 2019 002395 filed on Jan. 10, 2019, the content of which is included in the present application. Note that specific embodiments or examples made in the section of DESCRIPTION OF EMBODIMENTS merely clarify the technical content of the present disclosure, and the present disclosure should not be interpreted in a narrow sense by being limited only to such specific examples.

Features of the above-described preferred embodiments and the modifications thereof may be combined appropriately as long as no conflict arises.

While disclosed embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A contact terminal comprising:
a tubular body having conductivity and a tubular shape; and
a first central conductor having conductivity and a stick shape, wherein
the tubular body has a cross section perpendicular to an axial direction, the cross section having a shape that is rectangular or hexagonal, and
the first central conductor includes
a first insertion portion having a cross section perpendicular to an axial direction of the first central conductor, the cross section having a shape that is same as the shape of the cross section of the tubular body, the first insertion portion being inserted into one end portion side of the tubular body, and
a first projecting portion projecting from one end portion of the tubular body.

2. The contact terminal according to claim 1, wherein a length of a diagonal line in the cross section of the first insertion portion is larger than a length of one side of an inner wall in the cross section of the tubular body.

3. The contact terminal according to claim 1, further comprising a second central conductor having conductivity and a stick shape, wherein
the second central conductor includes
a second insertion portion having a cross section perpendicular to an axial direction of the second central conductor, the cross section having a shape that is same as the shape of the cross section of the tubular body, the second insertion portion being inserted into another end portion side of the tubular body, and
a second projecting portion projecting from another end portion of the tubular body,
the tubular body includes
a first spring portion that has a spiral shape and biases the first projecting portion in the projecting direction,
a tube portion connected to the first spring portion, and
a second spring portion that has a spiral shape and is connected to a side of the tube portion opposite to the first spring portion, and
the first spring portion and the second spring portion have spiral winding directions opposite to each other.

4. The contact terminal according to claim 1, wherein
the first insertion portion includes
a first swell portion provided in an end portion on an opposite side to the first projecting portion, and
a first stick-shaped body that extends from the first swell portion toward the first projecting portion and is thinner than the first swell portion.

5. The contact terminal according to claim 4, wherein the first swell portion is located in the tube portion.

6. The contact terminal according to claim 5, wherein a second insertion portion includes
a second swell portion provided in an end portion on an opposite side to the second projecting portion, and
a second stick-shaped body that extends from the second swell portion toward the second projecting portion and is thinner than the second swell portion.

7. The contact terminal according to claim 6, wherein the first swell portion and the second swell portion are located in the tube portion.

8. The contact terminal according to claim 1, wherein
the tubular body includes a spring portion that has a spiral shape and biases the first projecting portion in the projecting direction, and
the spring portion has the spiral winding direction that is constant.

9. The contact terminal according to claim 1, further comprising a biasing member that is provided in the tubular body and biases the first central conductor toward the one end portion side.

10. An inspection jig comprising:
a plurality of the contact terminals, each of the plurality of the contact terminals comprising:
a tubular body having conductivity and a tubular shape; and
a first central conductor having conductivity and a stick shape, wherein the tubular body has a cross section perpendicular to an axial direction, the cross section having a shape that is rectangular or hexagonal, and wherein the first central conductor includes
a first insertion portion having a cross section perpendicular to an axial direction of the first central conductor, the cross section having a shape that is same as the shape of the cross section of the tubular body, the first insertion portion being inserted into one end portion side of the tubular body, and
a first projecting portion projecting from one end portion of the tubular body; and
a support member that supports the plurality of the contact terminals.

11. The inspection jig according to claim 10, wherein the support member supports sides in the shape of the cross section of the tubular body of the plurality of the contact terminals in the same direction.

12. An inspection apparatus comprising:
the inspection jig according to claim 10; and
an inspection processing unit that performs an inspection of an inspection target on a basis of an electrical signal obtained by bringing the contact terminal into contact with an inspection point provided on the inspection target.

13. The contact terminal according to claim 2, further comprising a second central conductor having conductivity and a stick shape, wherein
the second central conductor includes
a second insertion portion having a cross section perpendicular to an axial direction of the second central conductor, the cross section having a shape that is same as the shape of the cross section of the tubular body, the second insertion portion being inserted into another end portion side of the tubular body, and
a second projecting portion projecting from another end portion of the tubular body,
the tubular body includes
a first spring portion that has a spiral shape and biases the first projecting portion in the projecting direction,
a tube portion connected to the first spring portion, and
a second spring portion that has a spiral shape and is connected to a side of the tube portion opposite to the first spring portion, and
the first spring portion and the second spring portion have spiral winding directions opposite to each other.

14. The contact terminal according to claim 2, wherein
the first insertion portion includes
a first swell portion provided in an end portion on an opposite side to the first projecting portion, and
a first stick-shaped body that extends from the first swell portion toward the first projecting portion and is thinner than the first swell portion.

15. The contact terminal according to claim 3, wherein
the first insertion portion includes
a first swell portion provided in an end portion on an opposite side to the first projecting portion, and
a first stick-shaped body that extends from the first swell portion toward the first projecting portion and is thinner than the first swell portion.

16. The contact terminal according to claim 2, wherein
the tubular body includes a spring portion that has a spiral shape and biases the first projecting portion in the projecting direction, and
the spring portion has the spiral winding direction that is constant.

17. The contact terminal according to claim 2, further comprising a biasing member that is provided in the tubular body and biases the first central conductor toward the one end portion side.

18. An inspection jig comprising:
a plurality of the contact terminals according to claim 2; and
a support member that supports the plurality of the contact terminals.

19. An inspection jig comprising:
a plurality of the contact terminals according to claim 3; and
a support member that supports the plurality of the contact terminals.

20. An inspection jig comprising:
a plurality of the contact terminals according to claim 4; and
a support member that supports the plurality of the contact terminals.
